(19) United States
(12) Patent Application Publication
(10) Pub. No.: US 2026/0221395 A1
(43) Pub. Date: Jul. 30, 2026

(54) UPPER ASSEMBLY AND SUBSTRATE PROCESSING APPARATUS

(71) Applicant: Tokyo Electron Limited, Tokyo (JP)

(72) Inventors: Satoshi SAITO, Miyagi (JP); Ryou SON, Miyagi (JP); Akiyoshi MITSUMORI, Miyagi (JP)

(73) Assignee: Tokyo Electron Limited, Tokyo (JP)

(21) Appl. No.: 19/578,544

(22) Filed: Mar. 25, 2026

Related U.S. Application Data
(63) Continuation of application No. PCT/JP2024/040854, filed on Nov. 18, 2024.

(30) Foreign Application Priority Data
Nov. 29, 2023 (JP) 2023-201947
Jul. 19, 2024 (JP) 2024-115624

(51) Int. Cl. H01J 37/32

(52) U.S. Cl. CPC H01J 37/32568; H01J 37/32091; H01J 37/32862; H01J 2237/334

(57) ABSTRACT

An upper assembly includes a ceiling plate, a base member, and at least one actuator. The ceiling plate is located above a processing space in a chamber in a substrate processing apparatus. The base member is located on the ceiling plate. The at least one actuator lifts the ceiling plate and urges the ceiling plate against the base member.

### CROSS-REFERENCE TO RELATED APPLICATIONS

This application is a continuation application of PCT Application No. PCT/JP2024/040854, filed on Nov. 18, 2024, which claims the benefit of priority from Japanese Patent Application No. 2024-115624, filed on Jul. 19, 2024, and Japanese Patent Application No. 2023-201947, filed on Nov. 29, 2023. The entire contents of the above listed PCT and priority applications are incorporated herein by reference.

### FIELD

Exemplary embodiments of the disclosure relate to an upper assembly and a substrate processing apparatus.

### BACKGROUND

A capacitively coupled plasma processing apparatus performs substrate processing as a type of a substrate processing apparatus. The capacitively coupled plasma processing apparatus includes an upper electrode. The upper electrode includes a cooling plate and an electrode plate. The cooling plate is located on the electrode plate. The electrode plate is fastened to the cooling plate with screws screwed into threaded holes in the electrode plate. Patent Literature 1 below describes the plasma processing apparatus including such an upper electrode.

### CITATION LIST

### Patent Literature

Patent Literature 1: Japanese Unexamined Patent Application Publication No. 2003-297806

### BRIEF SUMMARY

### Technical Problem

The technique according to one or more aspects of the present disclosure reduces the likelihood of a space being formed or widened between a ceiling plate and a base member in an upper assembly above a processing space in a chamber of a substrate processing apparatus.

### Solution to Problem

An upper assembly according to one exemplary embodiment is provided. The upper assembly includes a ceiling plate, a base member, and at least one actuator. The ceiling plate is located above a processing space in a chamber in a substrate processing apparatus. The base member is located on the ceiling plate. The at least one actuator lifts the ceiling plate and urges the ceiling plate against the base member.

### Advantageous Effects

The technique according to one exemplary embodiment reduces the likelihood of a space being formed or widened between the ceiling plate and the base member in the upper assembly in the processing space in the chamber of the substrate processing apparatus.

### BRIEF DESCRIPTION OF DRAWINGS

FIG. 1 is a diagram of a plasma processing system, illustrating an example structure.

FIG. 2 is a diagram of a capacitively coupled plasma processing apparatus, illustrating an example structure.

FIG. 3 is a diagram of an upper assembly according to one exemplary embodiment.

FIG. 4 is a diagram of an upper assembly according to another exemplary embodiment.

FIG. 5 is a diagram of multiple actuators and multiple temperature sensors in the upper assembly according to the other exemplary embodiment in an example layout.

FIG. 6 is a diagram of multiple actuators and multiple temperature sensors in an upper assembly according to still another exemplary embodiment in an example layout.

FIG. 7 is a diagram of an upper assembly according to still another exemplary embodiment.

FIG. 8 is a diagram of an upper assembly according to still another exemplary embodiment.

FIG. 9 is a diagram of an upper assembly according to still another exemplary embodiment.

FIG. 10 is a flowchart of a temperature control method in one exemplary embodiment.

FIG. 11 is a timing chart of a substrate processing method in one exemplary embodiment.

FIG. 12 is a block diagram of processing circuitry for performing computer-based operations described herein.

### DETAILED DESCRIPTION

Exemplary embodiments will now be described in detail with reference to the drawings. In the figures, like reference numerals denote like or corresponding components.

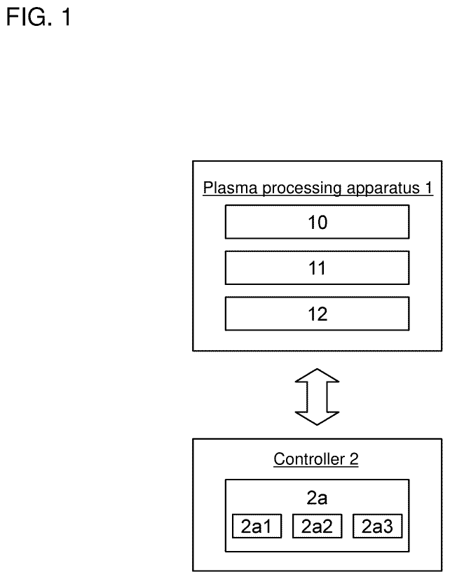

FIG. 1 is a diagram of a plasma processing system, illustrating an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators may be used, including an alternating current (AC) plasma generator and a direct current (DC) plasma generator. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

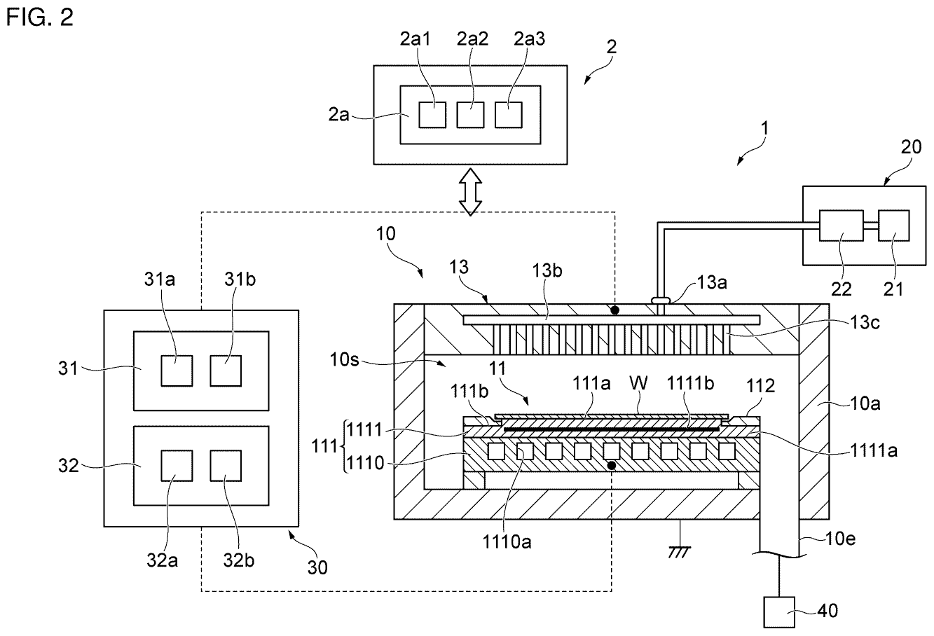

A capacitively coupled plasma processing apparatus with an example structure will now be described as an example of the plasma processing apparatus 1. FIG. 2 is a diagram of the capacitively coupled plasma processing apparatus, illustrating an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas guide unit. The gas guide unit allows at least one process gas to be introduced into the plasma processing chamber 10. The gas guide unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 may be electrically insulated from the housing of the plasma processing chamber 10.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is placed on the central area 111a of the body 111. The ring assembly 112 is placed on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b inside the ceramic member 1111a. The ceramic member 1111a includes the central area 111a. In one embodiment, the ceramic member 1111a also includes the annular area 111b. The annular area 111b may be included in another member surrounding the ESC 1111, such as an annular ESC or an annular insulating member. In this case, the ring assembly 112 may be located on either the annular ESC or the annular insulating member, or may be located on both the ESC 1111 and the annular insulating member. At least one RF/DC electrode coupled to an RF power supply 31 or a DC power supply 32, or both (described later) may be located in the ceramic member 1111a. In this case, at least one RF/DC electrode serves as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate to a target temperature. The temperature control module may include a heater, a heat transfer medium, a channel 1110a, or a combination of these. The channel 1110a carries a heat transfer fluid such as brine or gas. In one embodiment, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central area 111a.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one embodiment, the gas supply 20 supplies at least one process gas from each gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated source RF signal or the generated multiple source RF signals are provided to at least one lower electrode or at least one upper electrode, or both.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode or at least one upper electrode, or both. The voltage pulses may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may also include one or more positive voltage pulses and one or more negative voltage pulses within one cycle. The power supply 30 may include the first DC generator 32a and the second DC generator 32b in addition to the RF power supply 31. The first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

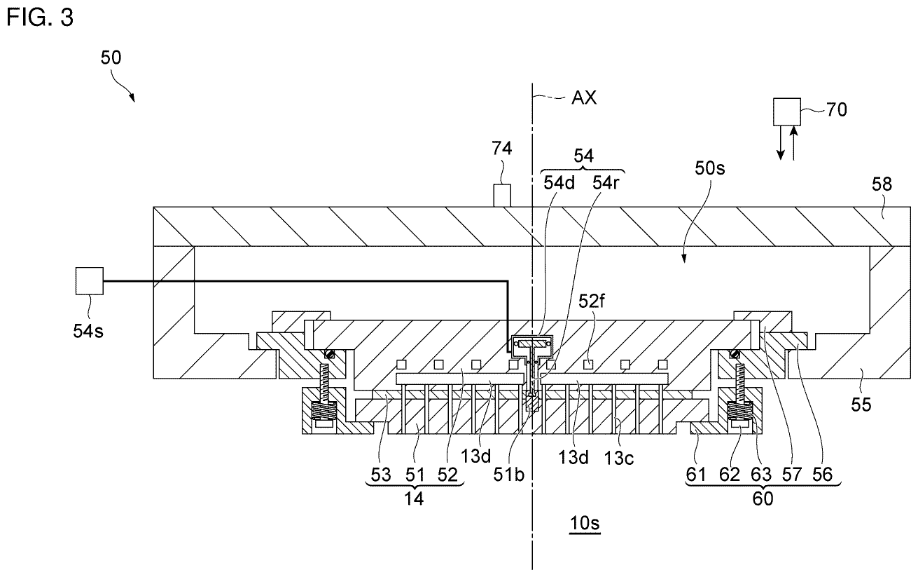

FIG. 3 will now be referred to. FIG. 3 is a diagram of an upper assembly according to one exemplary embodiment. An upper assembly 50 shown in FIG. 3 may be used in the substrate processing apparatus such as the plasma processing apparatus 1. In the embodiment shown in FIG. 3, the shower head 13 including an upper electrode 14 is electrically insulated from the housing of the plasma processing chamber 10 including a member 55 (described later).

As shown in FIG. 3, the upper assembly 50 may be located above the processing space 10s in the plasma processing apparatus 1. The upper assembly 50 includes a ceiling plate 51, a base member 52, and at least one actuator 54.

The ceiling plate 51 is located above the processing space 10s. The ceiling plate 51 defines the processing space 10s from above. The ceiling plate 51 may be substantially disk-shaped. The base member 52 is located on the ceiling plate 51. The base member 52 may be substantially disk-shaped. The base member 52 may include a refrigerant channel 52f extending in the base member 52. The refrigerant channel 52f is connected to a chiller unit 70. The refrigerant channel 52f receives a refrigerant supplied from the chiller unit 70. The refrigerant flows through the refrigerant channel 52f and returns to the chiller unit 70. The temperature of the base member 52 is adjusted by the refrigerant flowing through the refrigerant channel 52f. The temperature of the ceiling plate 51 is adjusted by transferring heat between the ceiling plate 51 and the base member 52.

The upper assembly 50 may further include a heat transfer sheet 53. The heat transfer sheet 53 is located between the upper surface of the ceiling plate 51 and the lower surface of the base member 52, and held between the ceiling plate 51 and the base member 52. When the upper assembly 50 includes no heat transfer sheet 53, the upper surface of the ceiling plate 51 and the base member 52 may be in contact with each other.

In one embodiment, the ceiling plate 51 and the base member 52 may serve as the upper electrode 14 described above in the capacitively coupled plasma processing apparatus 1. The upper electrode 14 may further include the heat transfer sheet 53, together with the ceiling plate 51 and the base member 52. In this case, the ceiling plate 51, the base member 52, and the heat transfer sheet 53 are formed from a conductive material. The ceiling plate 51 is formed from a conductive material such as silicon or metal (e.g., aluminum). The base member 52 is formed from a conductive material such as metal (e.g., aluminum). The heat transfer sheet 53 may be formed from a conductive material. The heat transfer sheet 53 may be elastic. The heat transfer sheet 53 is formed from, for example, carbon or a carbon-containing material.

In one embodiment, the upper assembly 50 may further include the member 55, a member 56, a member 57, and a member 58. The member 55 is formed from a conductive material such as metal (e.g., aluminum). The member 55 extends along the top of the side wall of the chamber 10 and is electrically grounded. The member 55 may be substantially cylindrical, and may have a smaller-diameter portion at its lower end. The smaller-diameter portion has a smaller inner diameter than an upper portion of the member 55 upward from the smaller-diameter portion.

The member 58 is located on the member 55. The member 58 is formed from a conductive material such as metal (e.g., aluminum). The member 58 is substantially disk-shaped and is electrically grounded. The member 55 and the member 58 define a space 50s.

The member 56 is formed from an insulating material such as quartz or alumina ceramic. The member 56 may be substantially annular. The member 56 has an inner edge located below the periphery of the base member 52 with its upper surface facing the lower surface of the periphery of the base member 52. The member 56 has an outer edge supported on the smaller-diameter portion of the member 55.

The member 57 may be formed from an insulating material such as quartz or alumina ceramic or a conductive material such as metal (e.g., stainless steel). The member 57 may be substantially annular. The member 57 has an inner edge located on the periphery of the base member 52 with its lower surface facing the upper surface of the periphery of the base member 52. The member 57 has an outer edge located on the outer edge of the member 56. The member 56 and the member 57 hold the periphery of the base member 52 between them.

In one embodiment, the upper assembly 50 may further include a clamp 60. The clamp 60 holds the periphery of the ceiling plate 51 and the periphery of the base member 52 between its upper and lower portions. The clamp 60 includes a member 61 as the lower portion. The clamp 60 may further include, as the upper portion, the member 56 and the member 57. The member 61 may be substantially annular. The member 61 may have an inner edge and an outer edge. The member 61 has an inner edge located below the periphery of the ceiling plate 51 with its upper surface facing the lower surface of the periphery of the ceiling plate 51. The member 61 has an outer edge located below the upper portion (e.g., the member 56 and the member 57) of the clamp 60. The clamp 60 may further include multiple screws 62, such as bolts, and multiple springs 63. The multiple screws 62 are screwed to the upper portion (e.g., the member 57) of the clamp 60. The heads of the screws 62 and the multiple springs 63 urge the member 61 against the upper portion (e.g., the member 56 and the member 57) of the clamp 60.

As described above, the upper assembly 50 includes the at least one actuator 54. The at least one actuator 54 suspends the ceiling plate 51 and urges the ceiling plate 51 against the base member 52. In other words, the at least one actuator 54 urges the ceiling plate 51 upward. The at least one actuator 54 may be controlled by the controller 2.

In the embodiment in FIG. 3, the upper assembly 50 includes a single actuator 54. As shown in FIG. 3, the actuator 54 may be connected to the center of the ceiling plate 51, or may urge the center of the ceiling plate 51 against the base member 52.

The actuator 54 may include a rod 54r and a drive 54d. The rod 54r extends upward from its lower end. The lower end of the rod 54r is engaged with the ceiling plate 51. The lower end of the rod 54r may be engaged with a bush 51b fixed to the ceiling plate 51. In the embodiment in FIG. 3, the lower end of the rod 54r is engaged with the center of the ceiling plate 51. As shown in FIG. 3, the lower end of the rod 54r may be engaged with the bush 51b fixed to the center of the ceiling plate 51. The drive 54d moves the rod 54r vertically. The drive 54d may be located in the base member 52.

In one embodiment, the at least one actuator 54 may be an air cylinder. In this case, the rod 54r is a cylinder rod, and the drive 54d is a cylinder head. In this case, the drive 54d, or more specifically, the cylinder head, is connected to an air feeder 54s with an air line. The at least one actuator 54 may be a hydraulic cylinder or any other actuator that can urge the ceiling plate 51 against the base member 52.

In the upper assembly 50 described above, the ceiling plate 51 is urged against the base member 52 by the at least one actuator 54. This structure reduces the likelihood of a space being formed or widened between the ceiling plate 51 and the base member 52. This maintains adhesion between the ceiling plate 51 and the base member 52 directly or indirectly through the heat transfer sheet 53. This also maintains thermal adhesion between the ceiling plate 51 and the base member 52 directly or indirectly through the heat transfer sheet 53.

In one embodiment, the plasma processing apparatus 1 may further include at least one temperature sensor 74. The at least one temperature sensor 74 measures the temperature of the ceiling plate 51. The at least one temperature sensor 74 may measure the temperature of the ceiling plate 51 in a portion of the ceiling plate 51 urged by the at least one actuator 54, or more specifically, in a portion of the ceiling plate 51 near the portion of the ceiling plate 51 to which the at least one actuator 54 is connected. In the embodiment shown in FIG. 3, a single temperature sensor 74 measures the temperature of the ceiling plate 51 in a portion near the center of the ceiling plate 51.

As described above, the shower head 13 including the upper electrode 14 is electrically insulated from the housing of the plasma processing chamber 10 including the member 55 in the embodiment in FIG. 3. In the embodiment in FIG. 3, the temperature sensor 74, which is a contactless thermometer such as a radiation thermometer, is thus located on the grounded member 58. In another embodiment, the temperature of the ceiling plate 51 may be measured using the temperature sensor 74, which is a contact thermometer such as a fluorescence lifetime thermometer. When the shower head 13 including the upper electrode 14 is electrically connected to the housing of the plasma processing chamber 10 including the member 55, the temperature sensor 74 may be used as a sensor that uses a change in electrical resistance, such as a temperature measurement resistor.

The controller 2 may control the at least one actuator 54 based on the temperature of the ceiling plate 51 measured by the at least one temperature sensor 74. The controller 2 may control the at least one actuator 54 to reduce the difference between the measured temperature of the ceiling plate 51 and a specified temperature for the ceiling plate 51.

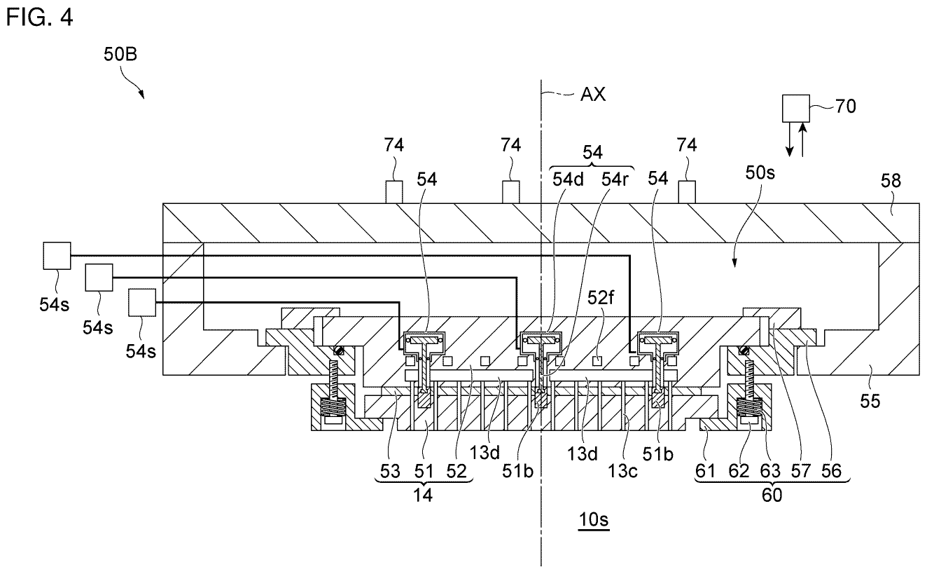

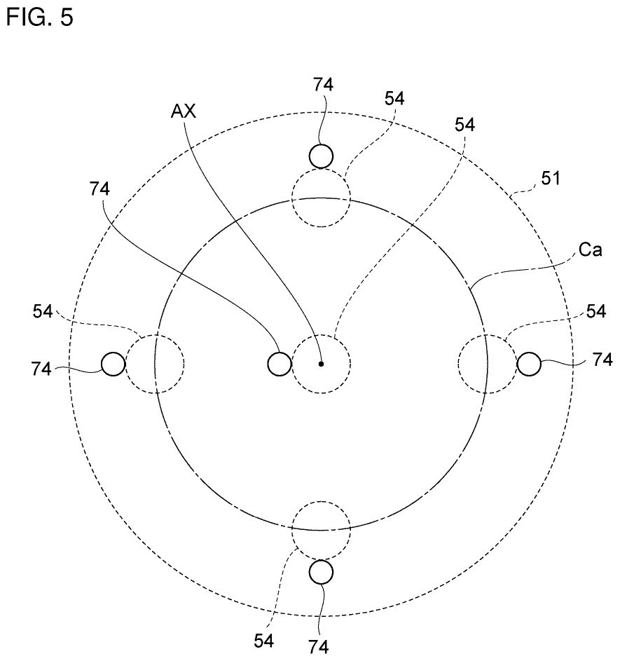

FIGS. 4 and 5 will now be referred to. FIG. 4 is a diagram of an upper assembly according to another exemplary embodiment. FIG. 5 is a diagram of multiple actuators and multiple temperature sensors in the upper assembly according to the other exemplary embodiment in an example layout. An upper assembly 50B shown in FIGS. 4 and 5 will now be described focusing on its differences from the upper assembly 50 shown in FIG. 3.

Similarly to the upper assembly 50, the upper assembly 50B may also be used in a substrate processing apparatus such as the plasma processing apparatus 1. The upper assembly 50B is also located in the processing space 10s in the plasma processing apparatus 1.

The upper assembly 50B includes multiple actuators 54. Each actuator 54 has the same structure as the actuator 54 in the upper assembly 50. The actuators 54 urge portions in the plane of the ceiling plate 51 against the base member 52. The actuators 54 may be individually controlled by the controller 2.

The actuators 54 may be arranged in at least one circle about a central axis AX of the ceiling plate 51. More specifically, the actuators 54 may be connected to multiple portions of the ceiling plate 51 in at least one circle about the central axis AX, and may urge the multiple portions against the base member 52.

In the embodiment in FIGS. 4 and 5, the actuators 54 are arranged in a circle Ca about the central axis AX. The actuators 54 may be arranged at equal intervals. In the embodiment in FIGS. 4 and 5, the actuators 54 are connected to the multiple portions of the ceiling plate 51 in a circle about the central axis AX having the same radius as the circle Ca, and urge the portions against the base member 52. The portions of the ceiling plate 51 may be arranged at equal intervals. The portions of the ceiling plate 51 in the circle about the central axis AX having the same radius as the circle Ca may be located nearer the periphery of the ceiling plate 51 than the center of the ceiling plate 51.

Similarly to the actuator 54 in the upper assembly 50, one of the actuators 54 may be connected to the center of the ceiling plate 51 to urge the center of the ceiling plate 51 against the base member 52.

Each actuator 54 in the upper assembly 50B may include the rod 54r and the drive 54d, similarly to the actuator 54 in the upper assembly 50. The rod 54r in each actuator 54 has a lower end engaged with the ceiling plate 51. The rod 54r in each actuator 54 may have a lower end engaged with the bush 51b fixed to the ceiling plate 51.

Each actuator 54 in the upper assembly 50B may be an air cylinder. In this case, the rod 54r is a cylinder rod, and the drive 54d is a cylinder head. In this case, the cylinder heads of the actuators 54 may be connected to the respective air feeders 54s with the corresponding air lines. Each actuator 54 in the upper assembly 50B may be a hydraulic cylinder or any other actuator that can urge the ceiling plate 51 against the base member 52.

In one embodiment, the plasma processing apparatus 1 including the upper assembly 50B may include at least one temperature sensor 74 for measuring the temperature distribution of the ceiling plate 51. The temperature distribution refers to the temperature distribution in the in-plane direction of the ceiling plate 51. In the embodiment in FIGS. 4 and 5, the plasma processing apparatus 1 includes multiple temperature sensors 74 for measuring the temperature distribution of the ceiling plate 51.

The multiple temperature sensors 74 may measure the temperature of the ceiling plate 51 in multiple portions of the ceiling plate 51 urged by the multiple actuators 54, or more specifically, in portions of the ceiling plate 51 near the portions of the ceiling plate 51 to which the actuators 54 are connected.

The controller 2 may control the multiple actuators 54 based on the measured temperature distribution of the ceiling plate 51. The controller 2 may control the actuators 54 to cause the temperature distribution of the ceiling plate 51 to approach a specified temperature distribution for the ceiling plate 51 based on the measured temperature distribution of the ceiling plate 51 and the specified temperature distribution. The specified temperature distribution may be a uniform temperature distribution.

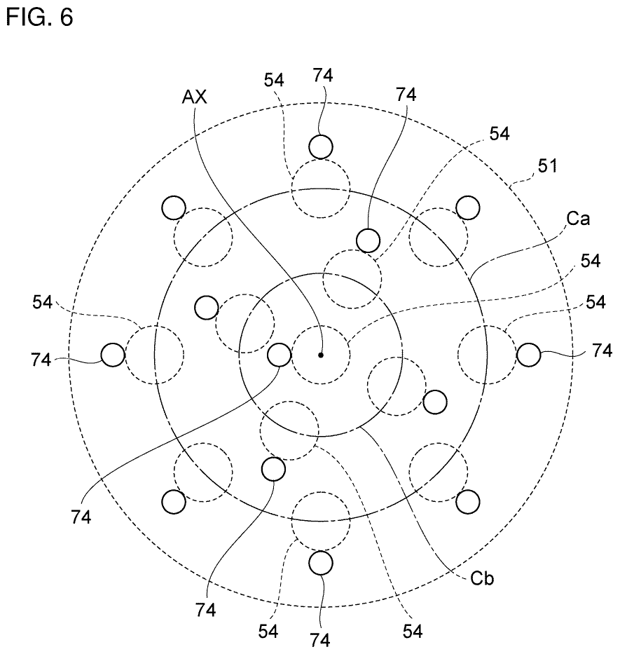

FIG. 6 will now be referred to. FIG. 6 is a diagram of multiple actuators and multiple temperature sensors in an upper assembly according to still another exemplary embodiment in an example layout. As shown in FIG. 6, multiple actuators 54 in an upper assembly 50B may be arranged in two circles Ca and Cb about the central axis AX. The two circles Ca and Cb are concentric. The actuators 54 in the upper assembly 50B may be arranged in three or more concentric circles about the central axis AX. The actuators 54 in each concentric circle may be arranged at equal intervals.

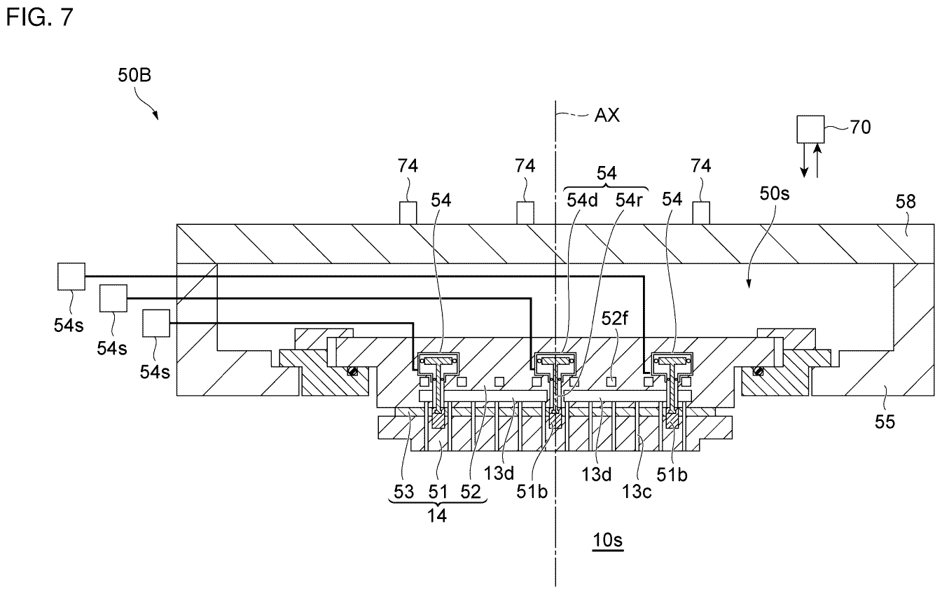

FIG. 7 will now be referred to. FIG. 7 is a diagram of an upper assembly according to still another exemplary embodiment. The upper assembly in one or more embodiments of the present disclosure, such as the upper assemblies 50 and 50B, may not include the clamp 60. As shown in FIG. 7, for example, the upper assembly 50B may not include the clamp 60. Similarly to the upper assembly 50, the upper assembly 50B may include the clamp 60 (refer to FIG. 4).

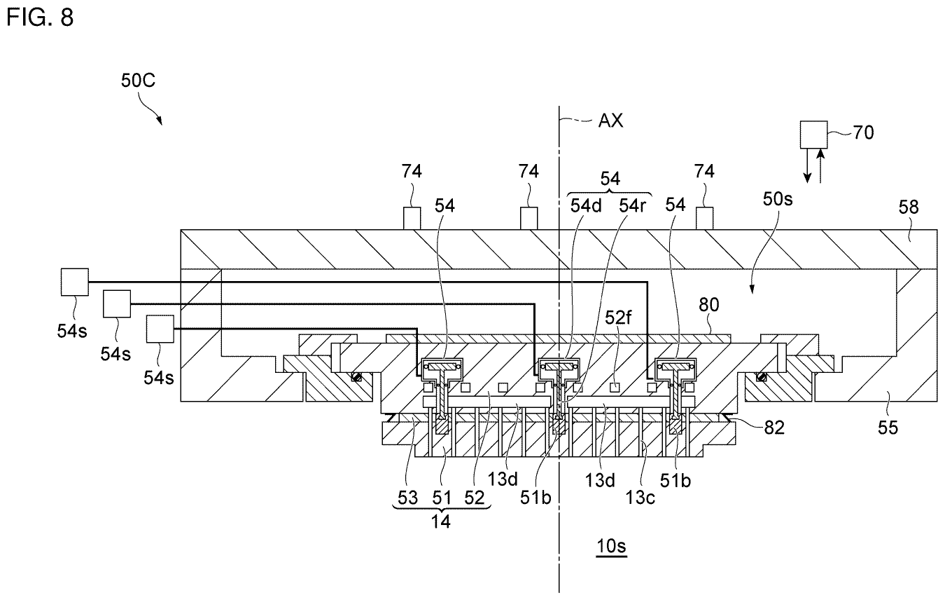

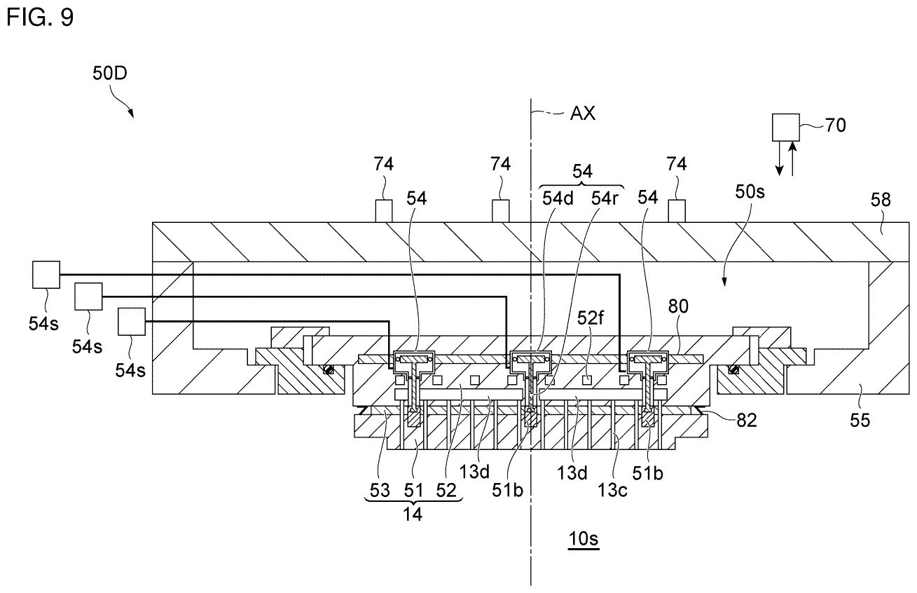

FIGS. 8 and 9 will be referred to. FIGS. 8 and 9 are diagrams of an upper assembly according to still another exemplary embodiment. An upper assembly 50C shown in FIG. 8 and an upper assembly 50D shown in FIG. 9 will now be described focusing on their differences from the upper assembly 50B shown in FIG. 7.

The upper assembly 50C and the upper assembly 50D may also be used in a substrate processing apparatus such as the plasma processing apparatus 1, similarly to the upper assembly 50B. Each of the upper assembly 50C and the upper assembly 50D is also located in the processing space 10s in the plasma processing apparatus 1.

The upper assembly 50C and the upper assembly 50D each further include a heater 80 and a seal 82. The heater 80 heats the ceiling plate 51 through the base member 52. The heater 80 may be controlled by the controller 2. In the upper assembly 50C, the heater 80 is located on the base member 52. In the upper assembly 50D, the heater 80 is located in the base member 52. In the upper assembly 50D, the heater 80 may be located in an area above the refrigerant channel 52f. The upper assembly 50 and the upper assembly 50B shown in FIG. 4 may also include the heater 80, similarly to the upper assembly 50C or the upper assembly 50D.

The seal 82 seals an area between the ceiling plate 51 and the base member 52, or more specifically, the area in which the heat transfer sheet 53 is located. The seal 82 is held between the ceiling plate 51 and the base member 52 to surround the heat transfer sheet 53. The seal 82 is elastic and maintains contact with the ceiling plate 51 and the base member 52 at any change in the distance between the ceiling plate 51 and the base member 52. The upper assembly 50 and the upper assembly 50B shown in FIG. 4 may also include the seal 82, similarly to the upper assembly 50C or the upper assembly 50D.

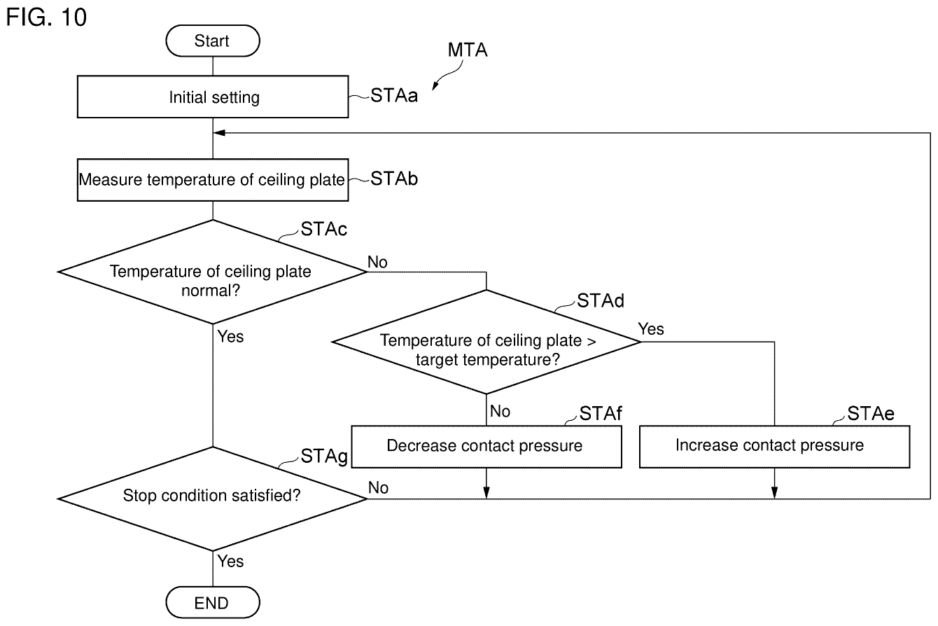

A temperature control method in an exemplary embodiment will now be described with reference to FIG. 10. FIG. 10 is a flowchart of a temperature control method in an exemplary embodiment. The temperature control method shown in FIG. 10 (hereafter referred to as a method MTA) is used in the plasma processing apparatus 1 including the upper assembly 50, 50B, 50C, or 50D to control the temperature of the ceiling plate 51. The method MTA may be performed by controlling the components of the plasma processing apparatus 1 with the controller 2. The method MTA may be performed during a process in the chamber 10 (e.g., plasma processing of a substrate in the chamber 10, such as plasma etching).

The method MTA starts from step STAa. In step STAa, the one or more actuators 54 are initialized to set the contact pressure of the ceiling plate 51 against the heat transfer sheet 53 to an initial state. In step STAb, the temperature of the ceiling plate 51 is measured using the one or more temperature sensors 74.

In step STAc, the determination is performed as to whether the measured temperature of the ceiling plate 51 is normal with respect to a target temperature of the ceiling plate 51. When the measured temperature of the ceiling plate 51 is not normal, the determination is performed as to whether the measured temperature of the ceiling plate 51 is higher than the target temperature in step STAd. When the measured temperature of the ceiling plate 51 is higher than the target temperature, the controller 2 controls the one or more actuators 54 to increase the contact pressure of the ceiling plate 51 against the heat transfer sheet 53 in step STAe. When the measured temperature of the ceiling plate 51 is lower than the target temperature, the controller 2 controls the one or more actuators 54 to decrease the contact pressure of the ceiling plate 51 against the heat transfer sheet 53 in step STAf. After step STAe and step STAf, the processing returns to step STAb.

When the measured temperature of the ceiling plate 51 is determined to be normal in step STAc, the determination is performed as to whether a stop condition is satisfied in step STAg. The stop condition is a predetermined condition for stopping the process in the chamber 10. When the stop condition is not satisfied, the processing returns to step STAb. When the stop condition is satisfied, the method MTA ends. As described above, the plasma processing apparatus 1 controls the temperature of the ceiling plate 51 by adjusting the contact pressure of the ceiling plate 51 against the heat transfer sheet 53.

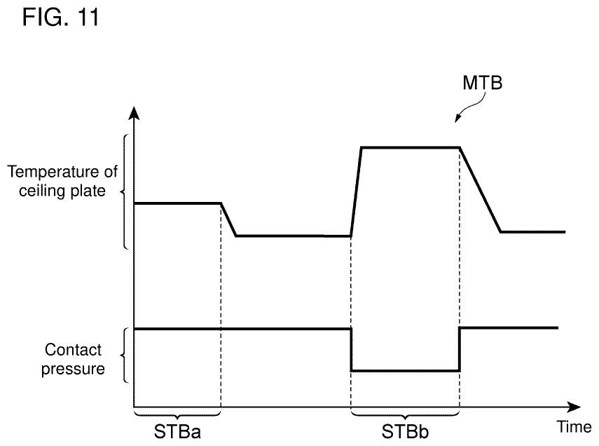

A substrate processing method in one exemplary embodiment will now be described with reference to FIG. 11. FIG. 11 is a timing chart of a substrate processing method according to one exemplary embodiment. FIG. 11 shows the temporal change in the temperature of the ceiling plate 51 and the temporal change in the contact pressure of the ceiling plate 51 against the heat transfer sheet 53 in the substrate processing method (hereafter referred to as a method MTB). The method MTB is performed by the plasma processing apparatus 1 including the upper assembly 50, 50B, 50C, or 50D. The method MTB may be performed by controlling the components of the plasma processing apparatus 1 with the controller 2.

The method MTB includes step STBa and step STBb. In step STBa, the controller 2 controls the components of the plasma processing apparatus 1 to perform a first process in the chamber 10. In step STBa (in other words, during the first process), the controller 2 controls the one or more actuators 54 to adjust the contact pressure of the ceiling plate 51 against the heat transfer sheet 53 to set the temperature of the ceiling plate 51 to a first target temperature. The first process may be plasma processing (e.g., plasma etching) of a substrate in the chamber 10.

Step STBb is performed after step STBa. In step STBb, the controller 2 controls the components of the plasma processing apparatus 1 to perform a second process in the chamber 10. In step STBb (in other words, during the second process), the controller 2 controls the one or more actuators 54 to adjust the contact pressure of the ceiling plate 51 against the heat transfer sheet 53 to set the temperature of the ceiling plate 51 to a second target temperature. The second target temperature is different from the first target temperature.

The second process may be plasma cleaning (in other words, dry cleaning) of the chamber 10. In this case, the second target temperature is higher than the first target temperature to volatilize the deposit on the surface of the chamber 10 quickly in cleaning and to exhaust the deposit. In this case, the contact pressure described above is lower during the second process than during the first process.

The plasma processing apparatus 1 can increase the temperature of the ceiling plate 51 by adjusting the contact pressure. The temperature of the ceiling plate 51 can thus be increased more quickly than when the heater 80 alone is used. The method MTB may also include heating the ceiling plate 51 with the heater 80 together with adjusting the contact pressure.

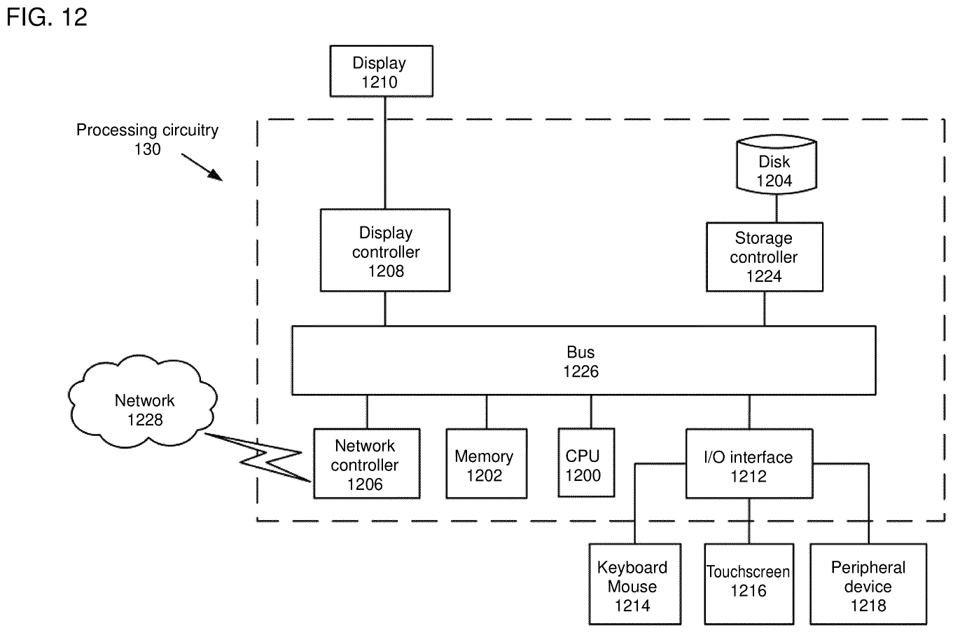

Example processing circuitry that may be used as one or more processing circuits will now be described. Examples of the processing circuitry include the controller 2 in the plasma processing apparatus 1. FIG. 12 is a block diagram of processing circuitry for performing computer-based operations described herein. FIG. 12 illustrates processing circuitry 130 that may be used to control any computer-based control processes. The descriptions or blocks in the flowcharts represent modules, segments, or portions of a code including one or more executable instructions for implementing specific logical functions or steps in the processes. Alternate implementations are included within the scope of the exemplary embodiments of the disclosure in which functions can be executed in an order different from the order shown or discussed, including substantially concurrently or in reverse order, depending on the functionality involved, as will be understood by those skilled in the art. The various elements, features, and processes described herein may be used independently of one another or may be combined in various ways. All possible combinations and sub-combinations are intended to fall within the scope of the disclosure.

In FIG. 12, the processing circuitry 130 includes a CPU 1200 that performs one or more of control processes described above or described below. The processing data and instructions may be stored in a memory 1202. These processing data and instructions may be stored in a storage medium disk 1204, such as an HDD or a portable storage medium, or may be stored remotely. Further, the techniques described in the scope of the claims are not limited to the form of the computer-readable media in which instructions for the inventive processes are stored. For example, the instructions may be stored in any other information processing device such as a compact disc (CD), a digital versatile disc (DVD), a flash memory, a RAM, a ROM, a programmable ROM (PROM), an erasable programmable ROM (EPROM), an electrically erasable programmable (EEPROM), a hard disk drive, or at least one of a server or a computer with which the processing circuitry 130 communicates.

The techniques described in the scope of the claims may be provided as a utility application, a background daemon, a component of an operating system, or a combination of these, or may be implemented in cooperation with the CPU 1200 and an operating system such as Microsoft Windows (registered trademark), UNIX (registered trademark), Solaris (registered trademark), LINUX (registered trademark), Apple MAC-OS, and other systems known to those skilled in the art.

The hardware elements to achieve the processing circuitry 130 can be implemented by various circuit elements. Further, each of the functions of the above-described embodiments may be implemented by circuitry, which includes one or more processing circuits. As shown in FIG. 12, the processing circuitry includes a specifically programmed processor, for example, a processor (CPU) 1200. The processing circuitry also includes devices such as an application-specific integrated circuit (ASIC) or known circuit components to perform the described functions.

In FIG. 12, the processing circuitry 130 includes the CPU 1200 that performs the processes described above. The processing circuitry 130 may be a general-purpose computer or a specific dedicated machine. In one embodiment, the processing circuitry 130 functions as a specific dedicated machine when the processor 1200 is programmed to control the plasma generator 12 and the gas supply 20, and alternatively or additionally, the at least one actuator 54.

Alternatively, or additionally, the CPU 1200 may be implemented on a field-programmable gate array (FPGA), an ASIC, a programmable logic device (PLD) or using a discrete logic circuit, as will be understood by those skilled in the art. Further, the CPU 1200 may be implemented as multiple processors cooperatively working in parallel to perform the instructions of the processes in the embodiments of the disclosure described above.

The processing circuitry 130 in FIG. 12 also includes a network controller 1206, such as an Intel Ethernet PRO network interface card from Intel Corporation of America, for connecting to a network 1228. As can be understood, the network 1228 may be a public network such as the Internet, a private network such as a LAN or wide area network (WAN), or any combination of these, or may also include a sub-network such as a public switched telephone network (PSTN) or an integrated services digital network (ISDN). The network 1228 may also be wired, such as an Ethernet network, or may be wireless such as a cellular network including Enhanced Data GSM Environment (EDGE), 3G, and 4G wireless cellular systems. The wireless network may also be Wi-Fi, Bluetooth (registered trademark), or in any other known wireless communication form.

The processing circuitry 130 further includes a display controller 1208, such as a graphics card or graphics adapter for interfacing with a display 1210, such as a monitor. A general purpose I/O interface 1212 interfaces with at least one of a keyboard or a mouse 1214 as well as with a touchscreen 1216 integral with or separate from the display 1210. The general-purpose I/O interface is also connected to various peripheral devices 1218, such as a printer and a scanner.

A storage controller 1224 connects the storage medium disk 1204 with a communication bus 1226, which may be an Industry Standard Architecture (ISA), Extended Industry Standard Architecture (EISA), Video Electronics Standards Association (VESA) Local Bus, or Peripheral Component Interconnect (PCI) for interconnecting all the components of the processing circuitry 130. The general features and functions of the display 1210, at least one of the keyboard or the mouse 1214, the display controller 1208, the storage controller 1224, the network controller 1206, a sound controller 1220, and the general purpose I/O interface 1212 will not be described herein for simplicity.

The exemplary circuit elements described in the context of the disclosure may be replaced with other elements and structured differently from the examples provided herein. Further, circuitry that performs the features described herein may be implemented by multiple circuit units (e.g., chips) or may incorporate these features into circuitry of a single chipset.

The functions and features described herein may also be implemented by various distributed components of the system. For example, one or more processors may perform the functions of the system. In this case, the processors may be distributed across multiple components communicating in a network. The distributed components may include one or more clients and server machines that can share processing, in addition to various human interfaces and communication devices (e.g., display monitors, smartphones, tablets, and personal digital assistants or PDAs). The network may be a private network, such as a LAN or WAN, or may be a public network, such as the Internet. Input into the system may be received directly by a user, or may be received remotely either in real time or as a batch process. Additionally, some implementations may be performed on modules or hardware not identical to those described. Other implementations are thus within the scope that may be claimed.

Although the exemplary embodiments have been described above, the embodiments are not restrictive, and various additions, omissions, substitutions, and changes may be made. The components in the different embodiments may be combined to form another embodiment.

For example, the upper assembly in one or more embodiments of the present disclosure, such as the upper assemblies 50, 50B, 50C, and 50D, may be used in another substrate processing apparatus other than the plasma processing apparatus.

Various exemplary embodiments E1 to E20 included in the disclosure will be described below.

E1

An upper assembly, comprising:
a ceiling plate located above a processing space in a chamber in a substrate processing apparatus;
a base member located on the ceiling plate; and
at least one actuator configured to lift the ceiling plate and urge the ceiling plate against the base member.

E2

The upper assembly according to E1, wherein
the at least one actuator includes an actuator connected to a center of the ceiling plate to urge the center of the ceiling plate against the base member.

E3

The upper assembly according to E1 or E2, wherein
the at least one actuator includes a plurality of actuators, and
the plurality of actuators urge a plurality of portions in a plane of the ceiling plate against the base member.

E4

The upper assembly according to E3, wherein
the plurality of portions are arranged in at least one circle about a central axis of the ceiling plate.

E5

The upper assembly according to any one of E1 to E4, wherein
the at least one actuator includes a rod and a drive configured to move the rod vertically, and
the rod has a lower end engaged with the ceiling plate and extends upward.

E6

The upper assembly according to E5, wherein
the drive is located in the base member.

E7

The upper assembly according to E5 or E6, wherein
the at least one actuator includes an air cylinder.

E8

The upper assembly according to any one of E1 to E7, further comprising:
a clamp holding a periphery of the ceiling plate and a periphery of the base member.

E9

The upper assembly according to any one of E1 to E8, further comprising:
a heat transfer sheet between the ceiling plate and the base member.

E10

The upper assembly according to any one of E1 to E9, wherein
the base member includes a refrigerant channel.

E11

The upper assembly according to any one of E1 to E10, wherein
the ceiling plate and the base member are included in an upper electrode in a capacitively coupled plasma processing apparatus being the substrate processing apparatus.

E12

A substrate processing apparatus, comprising:
a chamber; and
an upper assembly located above a processing space in the chamber, the upper assembly including
   a ceiling plate located above the processing space,
   a base member located on the ceiling plate, and
   at least one actuator configured to lift the ceiling plate and urge the ceiling plate against the base member.

E13

The substrate processing apparatus according to E12, further comprising:
at least one temperature sensor configured to measure a temperature of the ceiling plate; and
a controller configured to control the at least one actuator based on the temperature of the ceiling plate measured by the at least one temperature sensor.

E14

The substrate processing apparatus according to E12, wherein
the at least one actuator includes a plurality of actuators, and
the plurality of actuators urge a plurality of portions in a plane of the ceiling plate against the base member.

E15

The substrate processing apparatus according to E14, further comprising:
at least one temperature sensor configured to measure a temperature distribution of the ceiling plate; and
a controller configured to control the plurality of actuators based on the temperature distribution of the ceiling plate measured by the at least one temperature sensor.

E16

The substrate processing apparatus according to E15, wherein
the controller controls, based on the temperature distribution of the ceiling plate measured by the at least one temperature sensor and a specified temperature distribution for the ceiling plate, the plurality of actuators to cause the temperature distribution of the ceiling plate to approach the specified temperature distribution.

E17

The substrate processing apparatus according to E12, further comprising:
at least one temperature sensor configured to measure a temperature of the ceiling plate; and
a controller,
wherein the upper assembly further includes a heat transfer sheet between the ceiling plate and the base member,
the controller controls the at least one actuator to increase a contact pressure of the ceiling plate against the heat transfer sheet when the temperature of the ceiling plate measured by the at least one temperature sensor is higher than a target temperature, and
the controller controls the at least one actuator to decrease the contact pressure of the ceiling plate against the heat transfer sheet when the temperature of the ceiling plate measured by the at least one temperature sensor is lower than the target temperature.

E18

The substrate processing apparatus according to E12, further comprising:
at least one temperature sensor configured to measure a temperature of the ceiling plate; and
a controller,
wherein the upper assembly further includes a heat transfer sheet between the ceiling plate and the base member,
the controller controls the at least one actuator to adjust a contact pressure of the ceiling plate against the heat transfer sheet to set the temperature of the ceiling plate to a first target temperature during a first process in the chamber, and
the controller controls the at least one actuator to adjust the contact pressure of the ceiling plate against the heat transfer sheet to set the temperature of the ceiling plate to a second target temperature different from the first target temperature during a second process in the chamber.

E19

The substrate processing apparatus according to E18, wherein
the first process is plasma processing of a substrate in the chamber,
the second process is plasma cleaning of the chamber,
the second target temperature is higher than the first target temperature, and
the contact pressure during the second process is lower than the contact pressure during the first process.

E20

The substrate processing apparatus according to any one of E12 to E19, wherein
the substrate processing apparatus is a capacitively coupled plasma processing apparatus and further comprises a substrate support located in the chamber, and

the ceiling plate and the base member are included in an upper electrode in the capacitively coupled plasma processing apparatus.

The exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

### REFERENCE SIGNS LIST

Plasma processing apparatus
2 Controller
10 Chamber
11 Substrate support
50 Upper assembly
51 Ceiling plate
52 Base member
54 Actuator

1. An upper assembly, comprising:
a ceiling plate above a processing space in a chamber in a substrate processing apparatus;
a base member on the ceiling plate; and
at least one actuator configured to lift the ceiling plate and urge the ceiling plate against the base member.

2. The upper assembly according to claim 1, wherein
the at least one actuator includes an actuator connected to a center of the ceiling plate to urge the center of the ceiling plate against the base member.

3. The upper assembly according to claim 1, wherein
the at least one actuator includes a plurality of actuators, and
the plurality of actuators are configured to urge a plurality of portions in a plane of the ceiling plate against the base member.

4. The upper assembly according to claim 3, wherein
the plurality of portions are arranged in at least one circle about a central axis of the ceiling plate.

5. The upper assembly according to claim 1, wherein
the at least one actuator includes a rod and a drive configured to move the rod vertically, and
the rod has a lower end engaged with the ceiling plate and extends upward.

6. The upper assembly according to claim 5, wherein
the drive is in the base member.

7. The upper assembly according to claim 5, wherein
the at least one actuator includes an air cylinder.

8. The upper assembly according to claim 1, further comprising:
a clamp holding a periphery of the ceiling plate and a periphery of the base member.

9. The upper assembly according to claim 1, further comprising:
a heat transfer sheet between the ceiling plate and the base member.

10. The upper assembly according to claim 1, wherein
the base member includes a refrigerant channel.

11. The upper assembly according to claim 1, wherein
the ceiling plate and the base member are included in an upper electrode in a capacitively coupled plasma processing apparatus that is the substrate processing apparatus.

12. A substrate processing apparatus, comprising:
a chamber; and
an upper assembly above a processing space in the chamber, the upper assembly including
a ceiling plate above the processing space,
a base member on the ceiling plate, and
at least one actuator configured to lift the ceiling plate and urge the ceiling plate against the base member.

13. The substrate processing apparatus according to claim 12, further comprising:
at least one temperature sensor configured to measure a temperature of the ceiling plate; and
a controller configured to control the at least one actuator based on the temperature of the ceiling plate measured by the at least one temperature sensor.

14. The substrate processing apparatus according to claim 12, wherein
the at least one actuator includes a plurality of actuators, and
the plurality of actuators are configured to urge a plurality of portions in a plane of the ceiling plate against the base member.

15. The substrate processing apparatus according to claim 14, further comprising:
at least one temperature sensor configured to measure a temperature distribution of the ceiling plate; and
a controller configured to control the plurality of actuators based on the temperature distribution of the ceiling plate measured by the at least one temperature sensor.

16. The substrate processing apparatus according to claim 15, wherein
the controller is configured to control, based on the temperature distribution of the ceiling plate measured by the at least one temperature sensor and a specified temperature distribution for the ceiling plate, the plurality of actuators to cause the temperature distribution of the ceiling plate to approach the specified temperature distribution.

17. The substrate processing apparatus according to claim 12, further comprising:
at least one temperature sensor configured to measure a temperature of the ceiling plate; and
a controller,
wherein the upper assembly further includes a heat transfer sheet between the ceiling plate and the base member,
the controller is configured to control the at least one actuator to increase a contact pressure of the ceiling plate against the heat transfer sheet when the temperature of the ceiling plate measured by the at least one temperature sensor is higher than a target temperature, and
the controller is configured to control the at least one actuator to decrease the contact pressure of the ceiling plate against the heat transfer sheet when the temperature of the ceiling plate measured by the at least one temperature sensor is lower than the target temperature.

18. The substrate processing apparatus according to claim 12, further comprising:
at least one temperature sensor configured to measure a temperature of the ceiling plate; and
a controller,
wherein the upper assembly further includes a heat transfer sheet between the ceiling plate and the base member,
the controller is configured to control the at least one actuator to adjust a contact pressure of the ceiling plate against the heat transfer sheet to set the temperature of the ceiling plate to a first target temperature during a first process in the chamber, and
the controller is configured to control the at least one actuator to adjust the contact pressure of the ceiling plate against the heat transfer sheet to set the temperature of the ceiling plate to a second target temperature different from the first target temperature during a second process in the chamber.

19. The substrate processing apparatus according to claim 18, wherein
the first process is plasma processing of a substrate in the chamber,
the second process is plasma cleaning of the chamber,
the second target temperature is higher than the first target temperature, and
the contact pressure during the second process is lower than the contact pressure during the first process.

20. The substrate processing apparatus according to claim 12, wherein
the substrate processing apparatus is a capacitively coupled plasma processing apparatus and further comprises a substrate support in the chamber, and
the ceiling plate and the base member are in an upper electrode in the capacitively coupled plasma processing apparatus.
